(19) United States
(12) Patent Application Publication
(10) Pub. No.: US 2024/0057312 A1
(43) Pub. Date: Feb. 15, 2024

(54) ARRAY STRUCTURE, SEMICONDUCTOR STRUCTURE, AND METHOD FOR MANUFACTURING SEMICONDUCTOR STRUCTURE

(71) Applicant: CHANGXIN MEMORY TECHNOLOGIES, INC., Hefei City (CN)

(72) Inventors: Guangsu SHAO, Hefei (CN); Deyuan XIAO, Hefei (CN)

(21) Appl. No.: 18/171,422

(22) Filed: Feb. 20, 2023

Related U.S. Application Data
(63) Continuation of application No. PCT/CN2022/113969, filed on Aug. 22, 2022.

(30) Foreign Application Priority Data
Aug. 9, 2022 (CN) 202210951935.2

(51) Int. Cl. H10B 12/00

(52) U.S. Cl. CPC H10B 12/33; H10B 12/482; H10B 12/50; H10B 12/036; H10B 12/05

(57) ABSTRACT

An array structure, a semiconductor structure, and a method for manufacturing a semiconductor structure are provided. The array structure includes a plurality of memory cells, a plurality of word lines and a plurality of bit lines. Each memory cell includes a storage structure and a transistor arranged above the storage structure. Each transistor includes a columnar gate, a dielectric layer and an active layer. The dielectric layer covers a sidewall and a bottom surface of the columnar gate. The active layer covers a sidewall of the dielectric layer. A bottom surface of the active layer is electrically connected to the storage structure. Each bit line covers sidewalls of respective active layers in a first direction. Each word line extends in a second direction and is electrically connected to top surfaces of respective columnar gates. The first direction and the second direction intersect with each other.

### CROSS-REFERENCE TO RELATED APPLICATIONS

This is a continuation application of International Patent Application No. PCT/CN2022/113969, filed on Aug. 22, 2022, which claims priority to Chinese Patent Application No. 202210951935.2, filed on Aug. 9, 2022 and entitled “ARRAY STRUCTURE, SEMICONDUCTOR STRUCTURE, AND METHOD FOR MANUFACTURING SEMICONDUCTOR STRUCTURE”. The disclosures of International Patent Application No. PCT/CN2022/113969 and Chinese Patent Application No. 202210951935.2 are incorporated by reference herein in their entireties.

### BACKGROUND

A storage array architecture of a Dynamic Random Access Memory (DRAM) is an array composed of a memory cell (that is, 1T1C memory cell) including one transistor and one capacitor. A gate of the transistor is connected to a word line, a drain of the transistor is connected to a bit line, and a source of the transistor is connected to the capacitor.

In the related art, it is difficult to further miniaturize the dimension of the DRAM of the transistor based on a Vertical Gate All Around (VGAA) structure.

### SUMMARY

The disclosure relates to the technical field of semiconductors, and in particular to an array structure, a semiconductor structure, and a method for manufacturing a semiconductor structure.

In view of this, embodiments of the disclosure provide an array structure, a semiconductor structure, and a method for manufacturing a semiconductor structure.

According to an aspect of the disclosure, an array structure is provided, which includes a plurality of memory cells, a plurality of word lines and a plurality of bit lines.

Each of the plurality of memory cells includes a storage structure, and a transistor arranged above the storage structure.

Each of the transistors includes a columnar gate, a dielectric layer and an active layer. The dielectric layer covers a sidewall and a bottom surface of the columnar gate, the active layer covers at least a sidewall of the dielectric layer, and a bottom surface of the active layer is electrically connected to the storage structure.

Each of the plurality of bit lines covers sidewalls of respective active layers in a first direction.

Each of the plurality of word lines extends in a second direction and is electrically connected to top surfaces of respective columnar gates. The first direction and the second direction intersect with each other and are both perpendicular to the sidewalls of the active layers.

According to another aspect of the disclosure, a semiconductor structure is provided, which includes: a substrate, and at least one array structure arranged above the substrate. The at least one array structure includes a plurality of memory cells, a plurality of word lines and a plurality of bit lines.

Each of the plurality of memory cells includes a storage structure, and a transistor arranged above the storage structure.

Each of the transistors includes a columnar gate, a dielectric layer and an active layer. The dielectric layer covers a sidewall and a bottom surface of the columnar gate, the active layer covers at least a sidewall of the dielectric layer, and a bottom surface of the active layer is electrically connected to the storage structure.

Each of the plurality of bit lines covers sidewalls of respective active layers in a first direction.

Each of the plurality of word lines extends in a second direction and is electrically connected to top surfaces of respective columnar gates. The first direction and the second direction intersect with each other and are both perpendicular to the sidewalls of the active layers.

According to another aspect of the disclosure, a method for manufacturing a semiconductor structure is provided. The method includes the following operations.

A substrate is provided, and a plurality of storage structures arranged in an array in a first direction and in a second direction are formed on the substrate, in which the first direction and the second direction intersect with each other and are both parallel to a surface of the substrate.

A plurality of bit lines extending in the first direction are formed.

A plurality of transistors are formed, in which each of the plurality of transistors is arranged above a respective one of the plurality of storage structures, and each of the plurality of transistors includes a columnar gate, a dielectric layer and an active layer, in which the dielectric layer covers a sidewall and a bottom surface of the columnar gate, the active layer covers at least a sidewall of the dielectric layer, and a bottom surface of the active layer is electrically connected to the respective one of the plurality of storage structures, and in which each of the plurality of bit lines covers sidewalls of respective active layers.

A plurality of word lines extending in the second direction are formed, in which each of the plurality of word lines is electrically connected to top surfaces of respective columnar gates.

### BRIEF DESCRIPTION OF THE DRAWINGS

FIG. 1A is a three-dimensional diagram of a memory cell of a DRAM of a VGAA structure;

FIG. 1B is a partial three-dimensional diagram of a DRAM of a VGAA structure;

FIG. 2 is a flowchart of a method for manufacturing a semiconductor structure according to an embodiment of the disclosure; and

FIG. 3 to FIG. 17 are schematic cross-sectional views of a process of manufacturing a semiconductor structure according to an embodiment of the disclosure.

### DETAILED DESCRIPTION

In order to make technical solutions and advantages of the embodiments of the disclosure clearer, the technical solutions of the disclosure will be further described in detail below with reference to the accompanying drawings and embodiments. Although the exemplary implementation of the disclosure is shown in the accompanying drawings, it should be understood that the disclosure can be implemented in various forms and cannot be limited by the implementations illustrated herein. On the contrary, these embodiments are provided for more thoroughly understand the disclosure and to completely convey the scope of the disclosure to those skilled in the art.

The disclosure is described more specifically by way of examples in the following paragraphs with reference to the accompanying drawings. The advantages and features of the disclosure will become apparent in light of the following description and claims. It should be noted that the accompanying drawings are provided in a very simplified form not necessary drawn to exact scale, and are merely intended to facilitate convenience and clarify in explaining the embodiments of the disclosure.

It may be understood that the meaning of “on . . . ”, “over . . . ” and “above . . . ” in the disclosure should be read in the broadest manner, so that “on . . . ” not only means that it is “on” something without any intervening features or layers therebetween (that is, directly on something), but also includes the meaning of being “on” something with intervening features or layers therebetween.

In addition, for the convenience of description, spatial relation terms such as “on”, “above”, “over”, “top” and “upper” may be used herein to describe a relationship between an element or feature and another element or feature as shown in the figures. In addition to the orientations shown in the figures, the spatial relation terms are intended to include different orientations of the devices in use or operation. The device may be oriented in other ways (rotated by 90 degrees or other orientations), and the spatial descriptors used herein may also be explained accordingly.

In the embodiments of the disclosure, the term “substrate” refers to a material on which subsequent material layers are added. The substrate itself may be patterned. The material added on the top portion of the substrate may be patterned or may remain unpatterned. In addition, the substrate may contain various semiconductor materials, such as silicon, silicon germanium, germanium, gallium arsenide, indium phosphide, etc. Alternatively, the substrate may be made of a non-conductive material, such as glass, plastic, or sapphire wafers.

In the embodiments of the disclosure, the term “layer” refers to a portion of material that includes an area having a thickness. The layer may extend over the entirety of the structure below or above the layer, or may have an extent smaller than the extent of the structure below or above the layer. In addition, the layer may be an area of homogeneous or inhomogeneous continuous structure having a thickness less than the thickness of the continuous structure. For example, the layer may be located between the top and bottom surfaces of the continuous structure, or the layer may be arranged between any pairs of the horizontal faces at the top and bottom surfaces of the continuous structure. The layer may extend horizontally, vertically, and/or along an inclined surface. The layer may include a plurality of sub-layers. For example, the interconnection layer may include one or more conductor and contact sub-layers (in which interconnection wires and/or through hole contacts are formed), and one or more dielectric sub-layers.

In the embodiment of the disclosure, the terms “first”, “second” and the like are intended to distinguish similar objects, but do not necessarily indicate a specific order or sequence.

The semiconductor structure involved in the embodiments of the disclosure is at least a part that will be used in the subsequent process to form the structure of a final device. Herein, the final device may include a memory. The memory includes, but is not limited to, a DRAM. The DRAM is only taken as an example for description below.

It should be noted that, the description about the DRAM in the following embodiments is only used for illustrating the disclosure, but not for limiting the scope of the disclosure.

With the development of the DRAM technology, the dimension of the memory cell becomes smaller and smaller, and its array architecture changes from 8F² to 6F² to 4F². In addition, based on the requirements for ions and leakage current in the DRAM, the architecture of the memory changes from a planar array transistor to a recess gate array transistor, from the recess gate array transistor to a buried channel array transistor, and then from the buried channel array transistor to a vertical channel array transistor.

In some embodiments of the disclosure, regardless of the planar array transistor, the recess gate array transistor, the buried channel array transistor or the vertical channel array transistor, the DRAM is composed of a plurality of memory cells. The structure of each memory cell is mainly composed of one transistor and one memory cell (storage capacitor) controlled by the transistor. That is, the DRAM includes the architecture of one Transistor (T) and one Capacitor (C) (1T1C), and its main working principle is to use the amount of charges stored in the capacitor to represent whether a binary bit is 1 or 0.

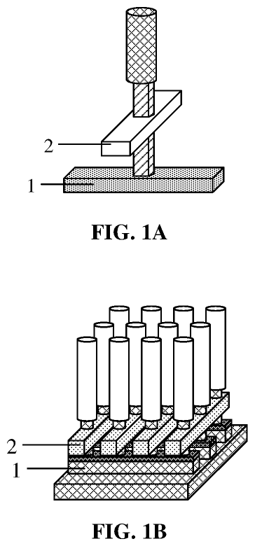

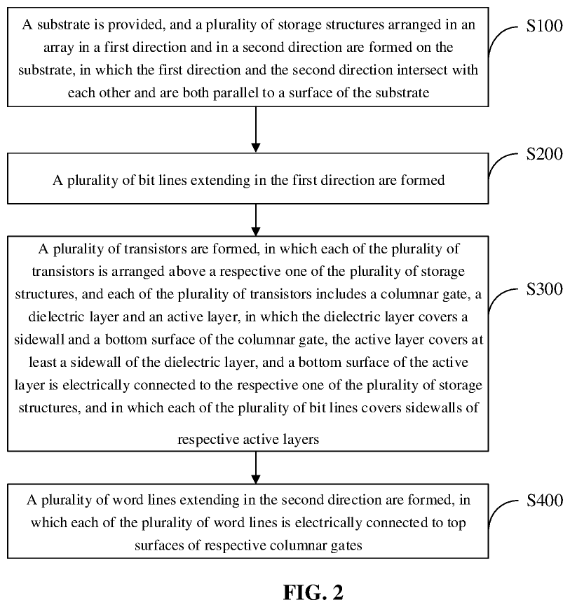

FIG. 1A is a three-dimensional diagram of a memory cell of a DRAM of a VGAA structure. FIG. 1B is a partial three-dimensional diagram of a DRAM of a VGAA structure. With reference to FIG. 1A and FIG. 1B, the VGAA structure adopts a 4F² array architecture. A gate surrounds the transistor. A bit line 1 is a bit line that is formed below a bit line 2 and forms a metal silicide by forming a metal layer and reacting the metal layer with silicon, which is also known as a buried bit line. A word line 2 surrounds the gate through a self-aligned process.

In the above embodiment, based on the substrate, the dimension of the VGAA structure is difficult to miniaturize, which does not facilitate the development of three-dimensional integration. Meanwhile, the process of substrate-based buried bit lines and the VGAA structure is complex. In addition, a peripheral circuit of the DRAM (Peri Sub Circuit) cannot be directly integrated on the bottom portion of the substrate.

Based on this, in order to solve one or more of the above problems, an embodiment of the disclosure provides a method for manufacturing a semiconductor structure. FIG. 2 is a flowchart of a method for manufacturing a semiconductor structure according to an embodiment of the disclosure. As shown in FIG. 2, the method for manufacturing the semiconductor structure provided in the embodiment of the disclosure includes the following operations.

In S100, a substrate is provided, and a plurality of storage structures arranged in an array in a first direction and in a second direction are formed on the substrate, in which the first direction and the second direction intersect with each other and are both parallel to a surface of the substrate.

In S200, a plurality of bit lines extending in the first direction are formed.

In S300, a plurality of transistors are formed, in which each of the plurality of transistors is arranged above a respective one of the plurality of storage structures, and each of the plurality of transistors includes a columnar gate, a dielectric layer and an active layer, in which the dielectric layer covers a sidewall and a bottom surface of the columnar gate, the active layer covers at least a sidewall of the dielectric layer, and a bottom surface of the active layer is electrically connected to the respective one of the plurality of storage structures, and in which each of the plurality of bit lines covers sidewalls of respective active layers.

In S400, a plurality of word lines extending in the second direction are formed, in which each of the plurality of word lines is electrically connected to top surfaces of respective columnar gates.

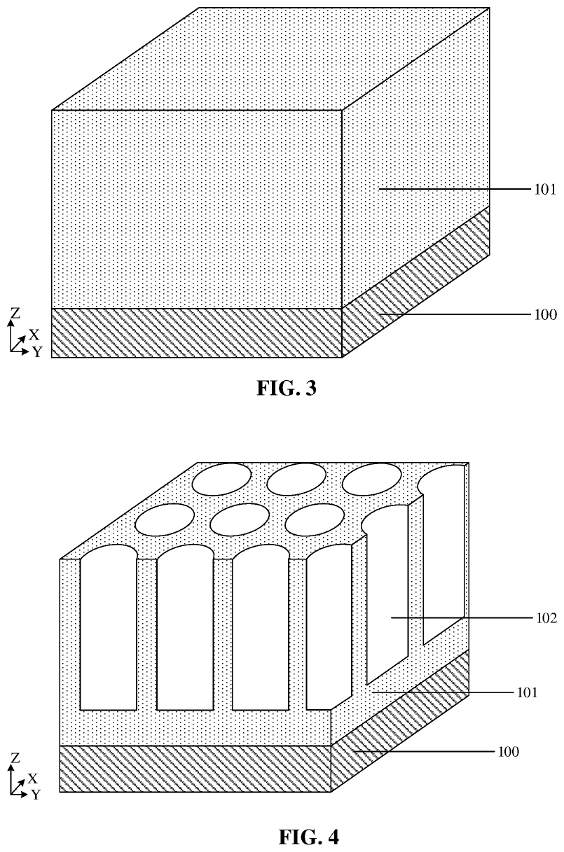

It should be understood that, the operations shown in FIG. 2 are not exclusive, and other operations may also be performed before, after or between any operations in the operations as shown. The sequence of the operations shown in FIG. 2 may be adjusted according to actual needs. FIG. 3 to FIG. 17 are schematic cross-sectional views of a process of manufacturing a semiconductor structure according to an embodiment of the disclosure. It should be noted that, FIG. 3 to FIG. 17 are schematic diagrams of a complete realization process reflecting the method for manufacturing the semiconductor structure, and some unmarked parts in some figures may be shared with each other. The method for manufacturing the semiconductor structure provided in the embodiment of the disclosure is further described in detail below with reference to FIG. 2, FIG. 3 to FIG. 17. In S100, a plurality of storage structures are mainly formed on the substrate.

In some specific embodiments, the substrate may include an elemental semiconductor material substrate (for example, a silicon (Si) substrate, a germanium (Ge) substrate, etc), a compound semiconductor material substrate (for example, a silicon germanium (SiGe) substrate, etc), a Silicon-On-Insulator (SOI) substrate, a Germanium-On-Insulator (GeOI) substrate, etc. Preferably, the substrate is a silicon substrate.

In some embodiments, before the plurality of storage structures are formed, a peripheral circuit may be formed on the substrate.

Herein, the semiconductor structure may form a memory. The memory includes at least one layer of array structure and a peripheral circuit. Each layer of array structure includes a plurality of memory cells. Each memory cell includes a storage structure and a transistor arranged above the storage structure. The peripheral circuit is connected to the array structure, and is configured to control the memory cell to achieve data writing, reading, refreshing, etc. In some specific embodiments, the peripheral circuit may include a command decoder, an address buffer, a line address multiplexer, a line decoder, memory body control logic, a column address latch, a column decoder, an input/output gating circuit, a data input/output buffer, etc. In some specific embodiments, the peripheral circuit may be formed by means of a Metal-Oxide-Semiconductor (MOS) technology.

It can be understood that, in the embodiments of the disclosure, the peripheral circuit may be directly formed on the substrate, and then the storage structure is continuously formed on the peripheral circuit. In this way, the peripheral circuit and the memory cell (including the storage structure and the transistor arranged above the storage structure) may be directly stacked on one substrate, so as to facilitate the three-dimensional integration and dimension miniaturization of the memory based on the semiconductor structure in the embodiments of the disclosure.

In some embodiments, the operation that the plurality of storage structures are formed on the substrate includes the following operations.

A first insulation layer is formed on the substrate, and a plurality of first grooves arranged in an array in the first direction and in the second direction are formed in the first insulation layer.

A lower electrode plate, a dielectric medium layer and an upper electrode plate material layer are successively formed on a surface of the first insulation layer and inner walls of the plurality of first grooves.

The upper electrode plate material layer is etched to form a plurality of upper electrode plates arranged in an array, in which each of the plurality of upper electrode plates corresponds to a respective one of the plurality of storage structures.

In some embodiments, the operation that the upper electrode plate material layer is etched includes the following operation.

A plurality of first shallow trenches spaced apart from each other and extending in the first direction are formed in the upper electrode plate material layer, and a plurality of second shallow trenches spaced apart from each other and extending in the second direction are formed, in which a bottom surface of each of the plurality of first shallow trenches and a bottom surface of each of the plurality of second shallow trenches are flush with a top surface of the dielectric medium layer, and the plurality of first shallow trenches and the plurality of second shallow trenches divide the upper electrode plate material layer into the plurality of upper electrode plates each corresponding to the respective one of the plurality of storage structures.

A process of forming the plurality of array storage structures 10 is described below in detail with reference to FIG. 3 to FIG. 9.

As shown in FIG. 3, a first insulation layer 101 is formed on the substrate 100. Herein, the first insulation layer 101 serves as a carrier for the storage structures 10, and the storage structures 10 are formed in the first insulation layer 101.

In some specific embodiments, a constituent material of the first insulation layer 101 includes, but is not limited to, silicon oxide (SiO₂).

In some specific embodiments, the method for forming the first insulation layer 101 includes, but is not limited to, a Physical Vapor Deposition (PVD) process, a Chemical Vapor Deposition (CVD) process, an Atomic Layer Deposition (ALD) process, etc.

Exemplarily, a layer of silicon oxide (SiO₂) is deposited on the substrate through a CVD process, and then the planarization is performed on the formed first insulation layer made of silicon oxide (SiO₂). The planarization process includes, but is not limited to, a Chemical Mechanical Polishing (CMP) technology.

Next, as shown in FIG. 4, a plurality of first grooves 102 arranged in an array in the first direction and in the second direction are formed in the first insulation layer 101.

Herein, the first direction is parallel to the surface of the substrate 100. The second direction intersects with the first direction, and is parallel to the surface of the substrate 100. A third direction is an extending direction of the first insulation layer 101, and is perpendicular to the top surface of the substrate 100.

Herein, the first direction intersects with the second direction. It can be understood that, an included angle between the first direction and the second direction ranges from 0 to 90 degrees.

In order to describe the disclosure clearly, in the following embodiments, the first direction being perpendicular to the second direction is taken as an example for description. Exemplarily, the first direction is an X-axis direction as shown in FIG. 3 to FIG. 17, the second direction is a Y-axis direction as shown in FIG. 3 to FIG. 17, and the third direction is a Z-axis direction as shown in FIG. 3 to FIG. 17. It should be noted that, the description about directions in the following embodiments is only used for illustrating the disclosure, but not for limiting the scope of the disclosure.

Herein, the storage structure 10 is formed in the first groove 102.

In the practical application, the bottom area of the first groove 102 may be set larger, and the spacing between two adjacent first grooves 102 may be set smaller. It can be understood that, with a certain surface area of the first insulation layer 101, the storage structure formed in the first groove 102 with a larger bottom area and smaller spacing has larger storage capacity and higher storage density.

In some specific embodiments, the method for forming the plurality of first grooves 102 includes, but is not limited to, a dry plasma etching process.

Next, as shown in FIG. 5, a lower electrode plate 103, a dielectric medium layer 104 and an upper electrode plate material layer 105 are successively formed on a surface of the first insulation layer 101 and inner walls of the plurality of first grooves 102.

Herein, the lower electrode plate 103 serves as a lower electrode plate of a capacitor.

In some specific embodiments, a material of the lower electrode plate 103 is a conductive material, including one or more of tungsten (W), titanium (Ti), nickel (Ni), aluminum (Al), platinum (Pt), ruthenium (Ru), ruthenium oxide (RuO), titanium nitride (TiN), or polysilicon.

In some specific embodiments, the method for forming the lower electrode plate 103 includes, but is not limited to, a PVD process, a CVD process, etc.

Herein, the dielectric medium layer 104 serves as a dielectric medium of the capacitor.

In some specific embodiments, a constituent material of the dielectric medium layer 104 includes a high dielectric constant (High-K) material. The High-K material generally refers to a material with a dielectric constant higher than 3.9, which is generally significantly higher than this value. In some specific examples, a material of the dielectric medium layer 104 may include, but is not limited to, aluminum oxide (Al₂O₃), zirconium oxide (ZrO), hafnium oxide (HfO₂), strontium titanate (SrTiO₃), etc.

In some specific embodiments, the method for forming the dielectric medium layer 104 includes, but is not limited to, a PVD process, a CVD process, etc.

Herein, the upper electrode plate material layer 105 is etched to form a plurality of upper electrode plates 106 arranged in an array. Each upper electrode plate corresponds to a respective one of the storage structures 10.

In some specific embodiments, a material of the upper electrode plate material layer 105 is a conductive material, including one or more of tungsten (W), titanium (Ti), nickel (Ni), aluminum (Al), platinum (Pt), ruthenium (Ru), ruthenium oxide (RuO), titanium nitride (TiN), or polysilicon.

In some specific embodiments, the method for forming the upper electrode plate material layer 105 includes, but is not limited to, a PVD process, a CVD process, etc.

Exemplarily, a layer of tungsten is deposited through a CVD process. The layer of tungsten covers the inner walls of the first grooves 102 and covers the top surface of the first insulation layer 101. Then, a layer of aluminum oxide is deposited on the surface of tungsten on the surface of the first insulation layer 101 and on the inner wall of the tungsten on the inner walls of the first grooves through a CVD process. Finally, a layer of tungsten is deposited on the top surface of the aluminum oxide and in the groove formed by the aluminum oxide through a CVD process, so that the tungsten is completely filled in the groove formed by the aluminum oxide.

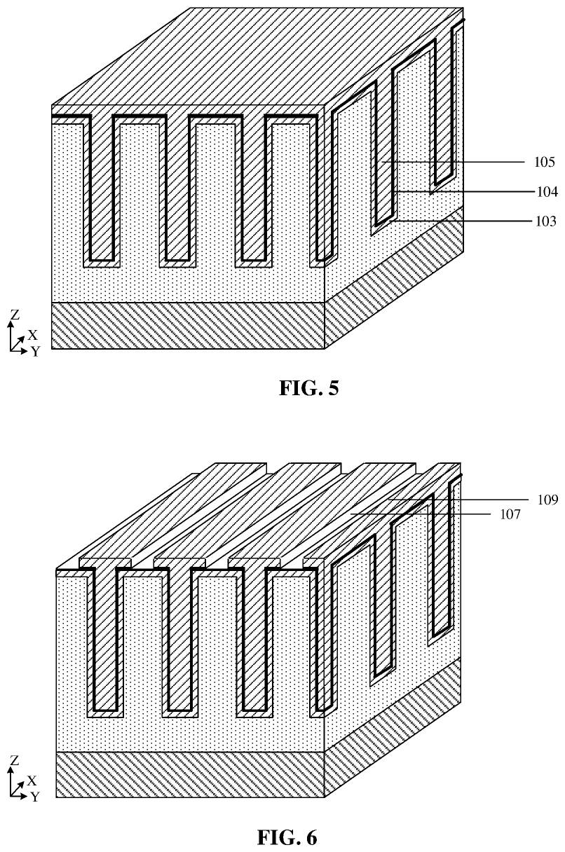

Next, as shown in FIG. 6, a plurality of first shallow trenches 107 spaced apart from each other and extending in the first direction are formed in the upper electrode plate material layer 105. A bottom surface of each of the plurality of first shallow trenches 107 is flush with a top surface of the dielectric medium layer 104. The plurality of first shallow trenches 107 divide the upper electrode plate material layer 105 into a plurality of upper electrode plate material strips 109 extending in the first direction.

In some specific embodiments, the method for forming the plurality of first shallow trenches 107 includes, but is not limited to, a dry plasma etching process.

Exemplarily, the upper electrode plate material layer 105 is etched through a dry etching process, so as to form the plurality of first shallow trenches 107 spaced apart from each other and extending in the first direction. The bottom surface of the first shallow trench 107 is flush with the top surface of the dielectric medium layer 104.

It can be understood that, the fact that the bottom surface of the first shallow trench 107 is flush with the top surface of the dielectric medium layer 104 indicates that the first shallow trenches 107 physically and completely separate the upper electrode plate material layer.

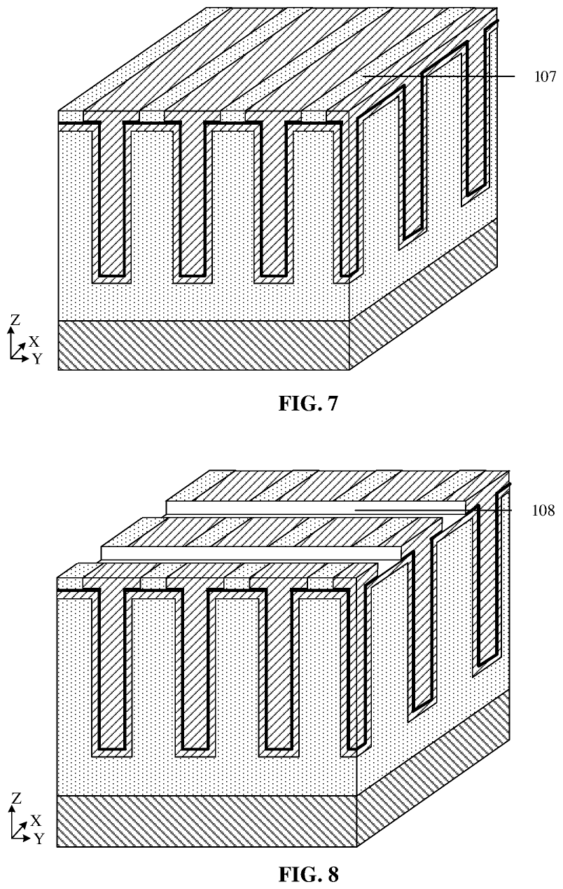

Next, as shown in FIG. 7, the first shallow trenches 107 are filled with a material layer. A top surface of the filled material layer is substantially flush with the top surface of the upper electrode plate material layer.

It should be noted that, “substantially flush” involved in the disclosure may be understood as approximately flush. It can be understood that, during the manufacturing of the memory, misalignment or non-flush caused by process error is also included in the scope of substantially flush.

In some specific embodiments, a material of the filled material layer in the first shallow trenches 107 is an insulation material, which includes, but is not limited to, silicon oxide (SiO₂).

In some specific embodiments, the method for filling the filled material layer in the first shallow trenches 107 includes, but is not limited to, a PVD process, a CVD process, etc.

Exemplarily, silicon oxide (SiO₂) is deposited in the first shallow trenches 107 through a CVD process, so as to allow the deposited silicon oxide (SiO₂) to cover the shallow trenches. By means of the CMP technology, the top surface of the silicon oxide (SiO₂) is substantially flush with the top surface of the upper electrode plate material layer.

Next, as shown in FIG. 8, a plurality of second shallow trenches 108 spaced apart from each other and extending in the second direction are formed in the upper electrode plate material strips 109 formed by the upper electrode plate material layer 105 and in the filled material layer formed in the first shallow trenches 107. A bottom surface of each of the plurality of second shallow trenches 108 is flush with the top surface of the dielectric medium layer 104. The plurality of first shallow trenches 107 and the plurality of second shallow trenches 108 divide the upper electrode plate material layer 105 into the plurality of upper electrode plates 106 extending in the second direction.

Herein, the formed upper electrode plate 106 serves as an upper electrode plate of the capacitor.

In some specific embodiments, the method for forming the plurality of second shallow trenches 108 includes, but is not limited to, a dry plasma etching process.

Exemplarily, the upper electrode plate material layer 105 and the first shallow trench material layer are etched through a dry etching process, so as to form the plurality of second shallow trenches 108 spaced apart from each other and extending in the second direction. The bottom surface of the second shallow trench 108 is flush with the top surface of the dielectric medium layer 104.

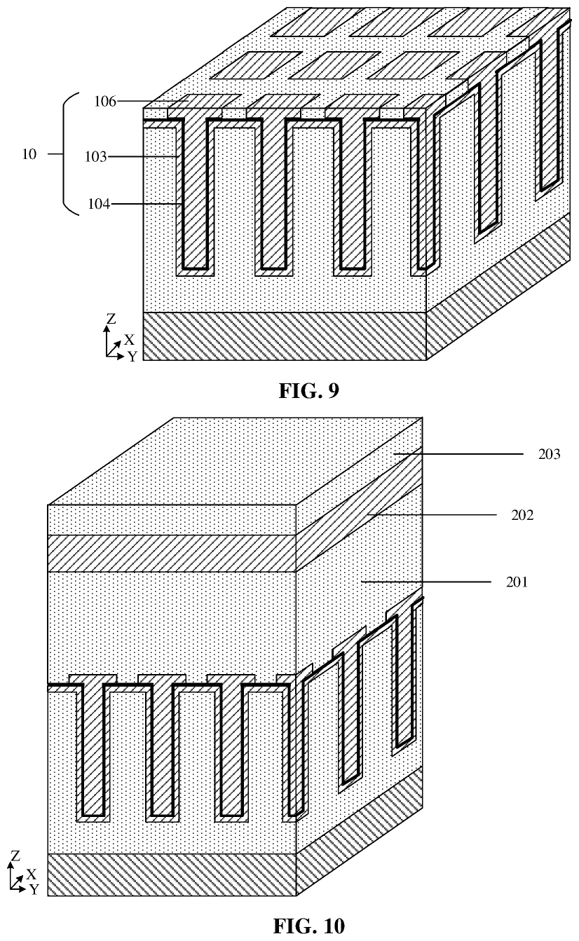

Next, as shown in FIG. 9, the plurality of second shallow trenches 108 are filled with a material layer. A top surface of the filled material layer is substantially flush with the top surface of the upper electrode plate material layer.

In some specific embodiments, a material of the filled material layer in the second shallow trenches 108 is an insulation material, which includes, but is not limited to, silicon oxide (SiO₂).

In some specific embodiments, the method for filling the filled material layer in the second shallow trenches 108 includes, but is not limited to, a PVD process, a CVD process, etc.

Exemplarily, silicon oxide (SiO₂) is deposited in the second shallow trenches 108 through a CVD process, so as to allow the deposited silicon oxide (SiO₂) to cover the shallow trenches. By means of the CMP technology, the top surface of the silicon oxide (SiO₂) is substantially flush with the top surface of the upper electrode plate material layer.

It can be understood that, the second shallow trenches 108 and the first shallow trenches 107 collectively divide the upper electrode plate material layer 105 into the upper electrode plates 106 arrayed in the first direction and in the second direction. The second shallow trenches 108, the insulation material in the second shallow trenches 108, the first shallow trenches 107, and the isolation material in the first shallow trenches 107 are together configured to divide the upper electrode plate material layer 105, so that each upper electrode plate, along with the dielectric medium layer arranged therebelow, and the lower electrode plate form an independent storage structure. All of the storage structures share one lower electrode plate. By controlling each individual upper electrode plate, the storage of charges can be achieved.

In S200, a plurality of bit lines extending in the first direction are mainly formed.

In some embodiments, the operation that the plurality of bit lines extending in the first direction are formed includes the following operations.

A second insulation layer, a first conductive material layer and a third insulation layer are successively formed on the plurality of storage structures, in which the second insulation layer, the first conductive material layer and the third insulation layer are stacked on one another.

A plurality of third trenches, which penetrate through the third insulation layer and the first conductive material layer and which extend in the first direction, are formed, in which the plurality of third trenches divide the first conductive material layer into a plurality of first conductive wires.

A plurality of vias are formed between any two adjacent third trenches of the plurality of third trenches, in which each of the plurality of vias penetrates through a respective one of the plurality of first conductive wires, and exposes an upper electrode plate of a respective one of the plurality of storage structures, and remaining portions of the plurality of first conductive wires form the plurality of bit lines.

A process of forming the bit lines is described below in detail with reference to FIG. 10 to FIG. 13.

As shown in FIG. 10, a second insulation layer 201, a first conductive material layer 202 and a third insulation layer 203 are successively formed on the plurality of storage structures. The second insulation layer, the first conductive material layer and the third insulation layer are stacked on one another.

Herein, the second insulation layer 201, the first conductive material layer 202 and the third insulation layer 203 serves as carriers for the transistor, and the transistor is formed in the second insulation layer 201, the first conductive material layer 202 and the third insulation layer 203.

In some specific embodiments, the method for forming the second insulation layer 201 includes, but is not limited to, a PVD process, a CVD process, etc.

In some specific embodiments, a constituent material of the second insulation layer 201 includes, but is not limited to, silicon oxide (SiO₂).

In some specific embodiments, the method for forming the first conductive material layer 202 includes, but is not limited to, a PVD process, a CVD process, etc.

In some specific embodiments, a material of the first conductive material layer 202 includes a metal material or a semiconductor conductive material, such as copper (Cu), cobalt (Co), tungsten (W), molybdenum (Mo), doped silicon, polysilicon, or any combination thereof.

In some specific embodiments, the method for forming the third insulation layer 203 includes, but is not limited to, a PVD process, a CVD process, etc.

In some specific embodiments, a constituent material of the third insulation layer 203 includes, but is not limited to, silicon oxide (SiO₂).

Exemplarily, a layer of silicon oxide (SiO₂) is deposited above the storage structures through a CVD process as the second insulation layer 201, and the planarization is performed on the second insulation layer by means of the CMP technology. A layer of tungsten is deposited on the second insulation layer made of silicon oxide (SiO₂) through a CVD process as the first conductive material layer 202, and the planarization is performed on the first conductive material layer by means of the CMP technology. Then a layer of silicon oxide (SiO₂) is deposited on the first conductive material layer made of tungsten through a CVD process as the third insulation layer 203, and the planarization is performed on the third insulation layer by means of the CMP technology.

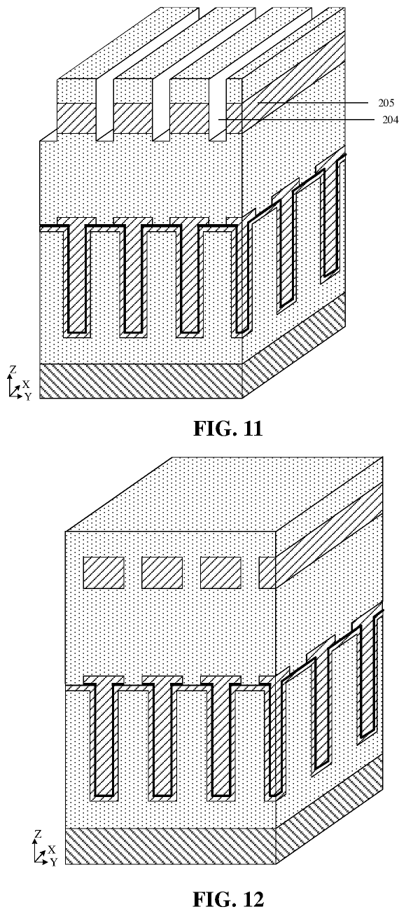

Next, as shown in FIG. 11, a plurality of third trenches 204, which penetrate through the third insulation layer 203 and the first conductive material layer 202 and which extend in the first direction, are formed. The plurality of third trenches 204 divide the first conductive material layer into a plurality of first conductive wires 205.

Herein, a depth value of the third trench 204 is greater than or equal to a sum of a thickness value of the third insulation layer 203 and a thickness value of the first conductive material layer 202. In this way, the first conductive material layer 202 can be guaranteed to be physically divided by the third trenches 204.

In some specific embodiments, the method for forming the plurality of third trenches 204 includes, but is not limited to, a dry plasma etching process.

Exemplarily, the formed second insulation layer, the first conductive material layer and the third insulation layer are etched through a dry etching process, so as to form the third trenches 204. The depth value of the third trench 204 is greater than or equal to the sum of the thickness value of the third insulation layer 203 and the thickness value of the first conductive material layer 202.

Next, as shown in FIG. 12, in some specific embodiments, before a plurality of vias 206 are formed, the third trenches 204 are filled with an insulation material.

Herein, the third trenches 204 and the insulation material in the third trenches can better divide the first conductive material layer 202 into the plurality of first conductive wires 205, so as to prevent electrical crosstalk between the first conductive wires 205.

In some specific embodiments, the insulation material filled in the third trenches 204 includes, but is not limited to, silicon oxide (SiO₂).

In some specific embodiments, the method for filling the third trenches 204 includes, but is not limited to, a PVD process, a CVD process, etc.

Exemplarily, silicon oxide (SiO₂) is deposited in the third trenches 204 through a CVD process, so as to allow silicon oxide (SiO₂) to cover an upper surface of the third insulation layer. The planarization is performed on the filled material by means of the CMP technology, so that the surface of the filled silicon oxide is substantially flush with the upper surface of the third insulation layer.

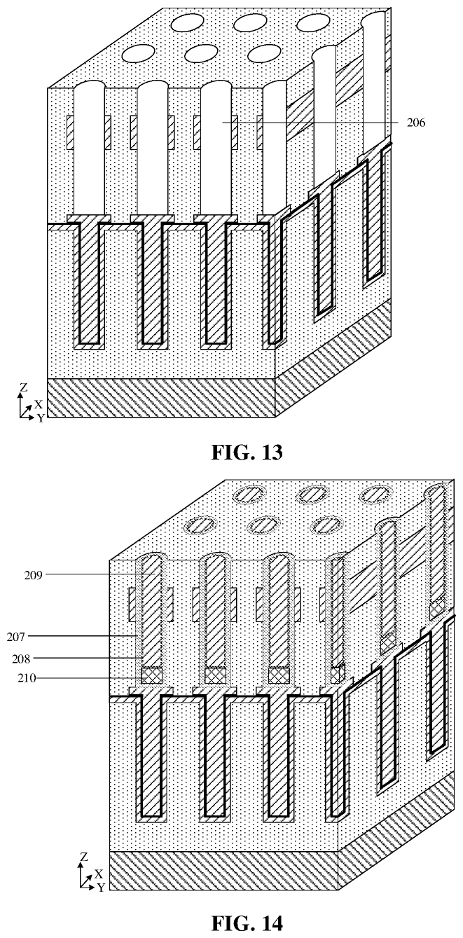

Next, as shown in FIG. 13, a plurality of vias 206 are formed between any two adjacent third trenches 204 of the plurality of third trenches. Each via penetrates through a respective one of the plurality of first conductive wires 205, and exposes an upper electrode plate of a respective one of the plurality of storage structures. Remaining portions of the plurality of first conductive wires form the plurality of bit lines.

In some specific embodiments, the method for forming the plurality of vias 206 includes, but is not limited to, a dry plasma etching process.

Exemplarily, the plurality of vias are formed by performing dry etching on the three-layer stacked structure formed of the second insulation layer, the first conductive material layer and the third insulation layer. Each via is arranged above the upper electrode plate of the respective storage structure.

Herein, the transistor may be formed in the formed via. The exposed upper electrode plate of the storage structure may be in direct contact with an electrode of the transistor formed in the via. This contact includes, but is not limited to, ohmic contact. The via penetrates through the first conductive wires 205, and the remaining portion of the first conductive wires forms the bit lines, which may be connected to the transistor formed in the via.

It can be understood that, in the embodiments of the disclosure, the first conductive wires are formed by etching the formed first conductive material layer, and then the transistor is manufactured in the first conductive wires, so that the formed first conductive wires may be directly electrically connected the transistors formed therein with each other. In this way, the complex process of the buried bit line in the foregoing embodiment can be avoided, so that the production process is simplified, and the reliability of the bit line connection is improved.

In S300, a plurality of transistors are mainly formed.

In some embodiments, the operation that the plurality of transistors are formed includes the following operation.

The active layer, an isolation layer, the dielectric layer and a second conductive material layer are successively formed in each of the plurality of vias, in which the active layer is formed on an inner wall of each of the plurality of vias, the isolation layer is formed at a bottom portion of each of the plurality of vias and covers an inner wall at a bottom portion of the active layer, the dielectric layer is formed on a surface of the sidewall of the active layer and on a top surface of the isolation layer, and the second conductive material layer is formed on a surface of the dielectric layer and is completely filled in each of the plurality of vias to form the columnar gates.

A process of forming the plurality of transistors is described below in detail with reference to FIG. 14.

As shown in FIG. 14, the active layer 207, the dielectric layer 208 and the second conductive material layer are successively formed in each via 206.

The active layer 207 here is formed on the inner wall and the bottom portion of the via 206. The dielectric layer 208 is formed on the inner wall and the bottom portion of the active layer 207. The second conductive material layer is formed on the surface of the dielectric layer, and is completely filled in the via to form the columnar gate 209.

Herein, the active layer 207 serves as a channel through which the electrons flow in the transistor. The dielectric layer 208 serves as a gate dielectric medium in the transistor. The columnar gate formed by the second conductive material layer may control the flow of the electrons in the active layer.

In some embodiments, a material of the active layer includes at least one of: indium oxide, gallium oxide, zinc oxide, indium gallium oxide, indium zinc oxide, gallium zinc oxide, indium gallium zinc oxide, indium tin oxide, indium tungsten oxide, or polysilicon.

In some specific embodiments, the material of the active layer is the indium gallium zinc oxide, such as InGaZnO₄.

It can be understood that, indium gallium zinc oxide may drive a large amount of current, so that the writing speed of the memory is faster when the indium gallium zinc oxide transistor is used in the memory. In addition, the transistor made based on an indium gallium oxide thin film has a very low cutoff current (Ioff) when the transistor is turned off, so that the current leakage of a DRAM unit can be effectively improved.

In addition, the transistor made based on an indium gallium zinc oxide thin film can also be effectively compatible with a Back End Of Line (BEOL). Therefore, the DRAM peripheral circuit can be moved under the array structure of the memory and the stacked DRAM unit can be integrated.

In some specific embodiments, the method for forming the active layer includes, but is not limited to, a PVD process, a CVD process, an ALD process, etc.

Exemplarily, the indium gallium zinc oxide is deposited through a Plasma Enhanced Atomic Layer Deposition (PEALD) process. Specifically, the PEALD of the indium gallium zinc oxide may be performed by using three precursors. During deposition, an indium oxide (InOₓ) layer, a gallium oxide (GaOₓ) layer and a zinc oxide (ZnOₓ) layer are deposited layer by layer in each microcirculation. Compared with a conventional sputtering process in which indium oxide (InOₓ), gallium oxide (GaOₓ) and zinc oxide (ZnOₓ) are simultaneously deposited, the deposited indium gallium zinc oxide that is deposited through a PEALD process has a uniform thickness and composition, a dense organization, and few pinholes.

It can be understood that, in the embodiments of the disclosure, the indium gallium zinc oxide deposited through a PEALD process can minimize the etching of the indium gallium zinc oxide. In this way, on the one hand, mask undercut caused by the isotropic wet etching process can be avoided, and on the other hand, the problems of huge maintenance cost of the main body of the dry etching device, the peripheral gas supply system, chlorine-containing waste gas treatment and power consumption, as well as the problems of short service life of devices due to particle pollution can be prevented.

In some embodiments, the area of the bottom surface of each formed active layer is less than an area of a top surface of each upper electrode plate.

It can be understood that, each via is arranged above the upper electrode plate of the respective storage structure. If the bottom area of each via is less than the area of the upper electrode plate of the storage structure above which the via is arranged, the bottom area of the active layer formed in this via is also less than the area of the upper electrode plate of the storage structure above which the active layer is arranged. In order to better electrically connect the transistor and the storage structure, the active layer shall fall in a projection area where the upper electrode plate of the storage structure is located. Preferably, the bottom surface of the active layer precisely falls in the middle of the projection area where the upper electrode plate is located. When the area of the upper electrode plate of the storage structure above which the active layer is arranged is greater than the bottom area of the active layer, the active layer can fall in the upper electrode plate of the storage structure more conveniently, so that a connection window between the transistor where the active layer is located and the storage structure is larger.

In some embodiments, before the dielectric layer 208 of the transistor is formed, a source and a drain are formed. This operation includes the following operations.

A bottom portion of each of the active layers is doped to form one of a source or a drain. A portion, which is in contact with the plurality of bit lines, of each of the active layers is doped to form the other one of the source or the drain.

In some specific embodiments, the method for forming the source and the drain includes, but is not limited to a doping process, a diffusion process, etc.

Exemplarily, the bottom portion of the active layer is doped through a diffusion process, so as to form an N-type or P-type semiconductor as the source. A portion of the active layer arranged at the bit lines is doped through a diffusion process, so as to form the N-type or P-type semiconductor as the drain.

Herein, it can be understood that, the portion of the active layer at the bottom portion of the via is doped through a diffusion process to form the source, and the portion of the active layer which is in contact with the bit lines is doped through a diffusion process to form the drain. The formed source is in direct contact with the upper electrode plate of the storage structure. The electrons flow into or flow out of the source via the active layer between the source and the drain, so that the electrons can be stored in the storage structure or be released from the storage structure. The formed source is directly connected to the upper electrode plate of the storage structure, so that the additional operation of forming a connection node between the storage structure and the transistor is simplified, thereby saving the process.

In some embodiments, after the active layer 207 of the transistor is formed, and before the dielectric layer 208 of the transistor is formed, the isolation layer 210 is formed. In some specific embodiments, a material of the isolation layer 210 is a non-conductive material, which includes, but is not limited to, oxynitride, silicon nitride, and silicon oxide.

In some specific embodiments, the method for forming the isolation layer 210 includes, but is not limited to, a PVD process, a CVD process, etc.

Exemplarily, after the source and the drain are formed in the active layer through a diffusion process, a layer of silicon oxide is deposited at the bottom portion of the active layer through a CVD process as the isolation layer 210.

Herein, it can be understood that, the drain, which covers the bottom portion of the active layer and is formed by diffusing at the bottom portion of the active layer, may cover a small position at the bottom portion of the active layer, so that the area of the drain can be effectively increased. In addition, compared with a situation in which the isolation layer 210 is not formed and a gate is directly filled, the thickness of the gate in the third direction is reduced, and the parasitic capacitance is reduced.

In some specific embodiments, the material of the dielectric layer includes, but is not limited to, silicon nitride, silicon oxide.

In some specific embodiments, the method for forming the dielectric layer includes, but is not limited to, a PVD process, a CVD process, etc.

In some specific embodiments, a material of the second conductive material layer serving as the gate includes a metal material or a semiconductor conductive material, such as copper (Cu), cobalt (Co), tungsten (W), molybdenum (Mo), doped silicon, polysilicon, or any combination thereof.

In some specific embodiments, the method for forming the second conductive material layer includes, but is not limited to, a PVD process, a CVD process, etc.

Exemplarily, a layer of silicon nitride is formed on the formed isolation layer through a CVD process as the dielectric layer. The dielectric layer is formed on the surface of the sidewall of the active layer and on the top surface of the isolation layer. A tungsten pillar completely filled in the via is formed on the surface of the dielectric layer made of silicon nitride through a CVD process as the columnar gate. By means of the CMP technology, the planarization is performed on the via in which the active layer, the dielectric layer and the second conductive material layer are formed, so that the top surfaces of the active layer, the dielectric layer and the second conductive material layer are substantially flush with the top surface of the third insulation layer.

Therefore, the storage structures, the bit lines and the transistors are formed.

In S400, a plurality of word lines extending in the second direction are mainly formed.

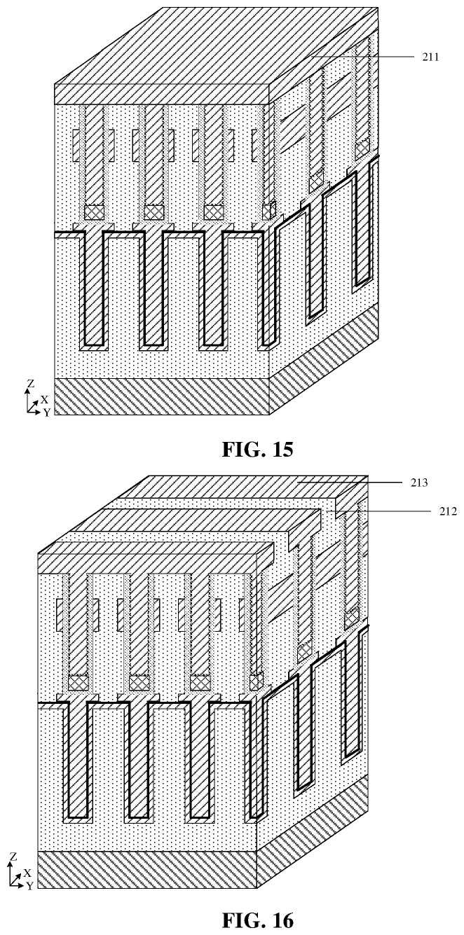

A process of forming the plurality of word lines is described below in detail with reference to FIG. 15 and FIG. 16.

In some embodiments, the plurality of word lines extending in the second direction are formed, in which each of the plurality of word lines is electrically connected to top surfaces of respective columnar gates.

As shown in FIG. 15, a third conductive material layer 211 is formed on the plurality of transistors.

In some specific embodiments, a material of the third conductive material layer includes a metal material or a semiconductor conductive material, such as copper (Cu), cobalt (Co), tungsten (W), molybdenum (Mo), doped silicon, polysilicon, or any combination thereof.

In some specific embodiments, the method for forming the third conductive material layer includes, but is not limited to, a PVD process, a CVD process, etc.

Exemplarily, a layer of tungsten is deposited on the formed transistors through a CVD process as the third conductive material layer 211. Then, the planarization is performed on the third conductive material layer 211 by means of the CMP technology.

Next, as shown in FIG. 16, a plurality of fourth shallow trenches 212 extending in the second direction are formed in the third conductive material layer, and the plurality of fourth shallow trenches are filled with an insulation material.

In some specific embodiments, the method for forming the plurality of fourth shallow trenches 212 includes, but is not limited to, a dry etching process, a wet etching process.

In some specific embodiments, the insulation material filled in the fourth shallow trenches 212 includes, but is not limited to, silicon oxide (SiO₂).

In some specific embodiments, a method for filling the insulation material in the fourth shallow trenches 212 includes, but is not limited to, a PVD process, a CVD process, etc.

Exemplarily, dry etching is performed on the third conductive material layer 211 to form the plurality of fourth shallow trenches 212 extending in the second direction. A depth value of the fourth shallow trench is greater than or equal to a thickness value of the third conductive material layer. The third conductive material layer divided by the fourth shallow trenches serves as the word lines 213 and is arranged above the transistors arrayed in the second direction. A layer of silicon oxide is deposited in the fourth shallow trenches 212 through a CVD process, and then the planarization is performed on the generated silicon oxide by means of the CMP technology, so that the top surface of the silicon oxide is substantially flush with the top surface of the third conductive material layer.

Herein, it can be understood that, like forming the bit lines by etching and filling as described above, the insulation material is filled in the fourth shallow trenches, so that the third conductive material layer 211 can be better divided into the plurality of word lines, so as to prevent electrical crosstalk between the word lines 213.

Therefore, a semiconductor structure including the word lines, the bit lines, the transistors and the storage structures is manufactured.

In some embodiments, a plurality of array structures stacked on the substrate are formed.

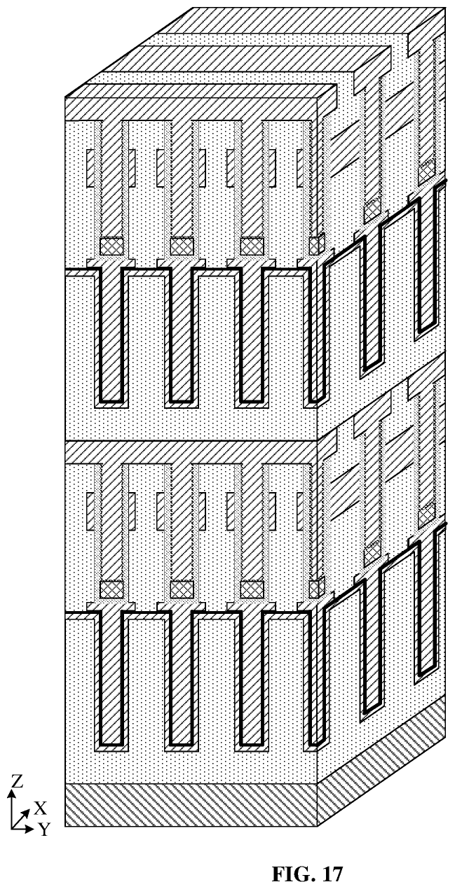

As shown in FIG. 17, the storage structures are formed on the transistors again in the same manner, and the transistors are then formed on the storage structures, and so on.

Exemplarily, an insulation layer made of silicon oxide (SiO₂) is formed on the word lines of the transistors through a CVD process. Grooves are formed in the silicon oxide (SiO₂) layer through a dry etching process. A layer of tungsten is formed in the grooves through a CVD process as the lower electrode plate. A layer of aluminum oxide is formed on the tungsten layer through a CVD process as the dielectric medium layer. Then, a layer of tungsten is formed on the aluminum oxide through a CVD process as the conductive material layer, and the conductive material layer is etched through a dry etching process to form shallow trenches respectively extending in the first direction and in the second direction. The shallow trenches divide the conductive material layer into the upper electrode plates. Each upper electrode plate is arranged above a respective groove. The insulation layer made of silicon oxide is deposited in the shallow trenches through a CVD process. In this way, the storage structures are formed. An insulation layer made of silicon oxide, a conductive material layer made of tungsten and an insulation layer made of silicon oxide are successively formed above the storage structures through a CVD process. Trenches extending in the first direction are formed in the topmost insulation layer made of silicon oxide and in the conductive material layer made of tungsten through a dry etching process. An insulation layer made of silicon oxide is formed in the trenches through a CVD process. The trenches divide the tungsten layer into conductive strips extending in the first direction. Vias are formed at the conductive strips through a dry etching process. Each via is arranged above a respective upper electrode plate. An active layer made of indium gallium zinc oxide is formed in the via through a CVD process. The P-type drain is formed by diffusing and doping the bottom portion of the active layer, and the P-type source is formed by diffusing and doping the active layer near the conductive strips. Through a CVD process, an isolation layer made of silicon oxide, a dielectric layer made of silicon nitride and a gate made of tungsten are formed on the active layer on which the source and the drain are formed. A layer of tungsten is formed on the formed transistors through a CVD process. Trenches extending in the second direction are formed on the tungsten layer through a dry etching process, so that the trenches divide the tungsten layer into the bit lines extending in the second direction.

It can be understood that, the semiconductor structure with a multi-layer of memory cells thus formed can effectively increase the storage density per unit area.

An embodiment of the disclosure provides a method for manufacturing a semiconductor structure, which includes the following operations. A substrate is provided, and a plurality of storage structures arranged in an array in a first direction and in a second direction are formed on the substrate, in which the first direction and the second direction intersect with each other and are both parallel to a surface of the substrate. A plurality of bit lines extending in the first direction are formed. A plurality of transistors are formed, in which each of the plurality of transistors is arranged above a respective one of the plurality of storage structures, and each of the plurality of transistors includes a columnar gate, a dielectric layer and an active layer, in which the dielectric layer covers a sidewall and a bottom surface of the columnar gate, the active layer covers at least a sidewall of the dielectric layer, and a bottom surface of the active layer is electrically connected to the respective one of the plurality of storage structures, and in which each of the plurality of bit lines covers sidewalls of respective active layers. A plurality of word lines extending in the second direction are formed, in which each of the plurality of word lines is electrically connected to top surfaces of respective columnar gates. The transistor structure provided in the embodiments of the disclosure is a structure in which a channel surrounds a gate. The layer-by-layer surrounding features of this structure are easily formed by successive growing in a via structure, so that the dimension of the entire transistor is easily limited within a dimension occupied by the via structure. Compared with the conventional VGAA, the channel occupies the via, which is more conducive to miniaturize the dimension of the transistor of the structure in which the channel surrounds the gate. In addition, the bottom surface of the active layer is directly electrically connected to the storage structure, so that the manufacturing operations of the connection nodes are saved, the process is simplified, and the production efficiency is improved.

According to another aspect of the disclosure, an embodiment of the disclosure further provides an array structure, which includes a plurality of memory cells, a plurality of word lines and a plurality of bit lines.

Each of the plurality of memory cells includes a storage structure, and a transistor arranged above the storage structure.

Each of the transistors includes a columnar gate, a dielectric layer and an active layer. The dielectric layer covers a sidewall and a bottom surface of the columnar gate. The active layer covers at least a sidewall of the dielectric layer. A bottom surface of the active layer is electrically connected to the storage structure.

Each of the plurality of bit lines covers sidewalls of respective active layers in a first direction. Each of the plurality of word lines extends in a second direction and is electrically connected to top surfaces of respective columnar gates. The first direction and the second direction intersect with each other and are both perpendicular to the sidewalls of the active layers.

In some embodiments, an area of the bottom surface of each of the active layers is less than an area of a top surface of each upper electrode plate.

In some embodiments, each of the transistors further includes an isolation layer. Each of the isolation layers is arranged between a bottom surface of a respective one of the dielectric layers and the bottom surface of a respective one of the active layers.

In some embodiments, one of a source or a drain of each of the transistors is arranged in a portion, which is in contact with the plurality of bit lines, of a respective one of the active layers, and the other one of the source or the drain of each of the transistors is arranged at a bottom portion of the respective one of the active layers.

The embodiments of the disclosure provide an array structure, a semiconductor structure, and a method for manufacturing a semiconductor structure. In the embodiments of the disclosure, the formed transistor includes a columnar gate, a dielectric layer and an active layer. The dielectric layer covers a sidewall and a bottom surface of the columnar gate, the active layer covers at least a sidewall of the dielectric layer, and a bottom surface of the active layer is electrically connected to the storage structure. That is to say, the transistor structure provided in the embodiments of the disclosure is a structure in which a channel surrounds a gate. The layer-by-layer surrounding features of this structure are easily formed by successively growing in a via structure, so that the dimension of the entire transistor is easily limited within a dimension occupied by the via structure. Compared with the conventional VGAA, the channel occupies the via, which is more conducive to miniaturize the dimension of the transistor of the structure in which the channel surrounds the gate. In addition, the bottom surface of the active layer is directly electrically connected to the storage structure, so that the manufacturing operations of the connection nodes are saved, the process is simplified, and the production efficiency is improved.

According to another aspect of the disclosure, an embodiment of the disclosure further provides a semiconductor structure, which includes a substrate, and at least one array structure as described above, which is arranged above the substrate.

In some embodiments, the semiconductor structure includes a plurality of array structures. The plurality of array structures are stacked on one another in a direction perpendicular to the substrate.

In some embodiments, in the semiconductor structure as described above, the substrate includes a peripheral circuit. The at least one array structure is electrically connected to the peripheral circuit.

The semiconductor structure and memory provided in the above embodiments have been described in detail on the method side, which are not repeated herein.

In the several embodiments provided in the disclosure, it should be understood that the disclosed device and method may be implemented in non-target manners. The device embodiments described above are merely exemplary. For example, the unit division is merely logical function division and may be other division in an actual implementation. For example, a plurality of units or components may be combined or integrated into another system, or some features may be ignored or not performed. In addition, the displayed or discussed components may be coupled or directly coupled to each other.

The features disclosed in several method or device embodiments provided in the disclosure may be arbitrarily combined without conflicts, so as to obtain new method embodiments or device embodiments.

The above are only the specific implementations of the disclosure, but the protection scope of the disclosure is not limited thereto. Any skilled in the art, within the technical scope disclosed by the disclosure, may easily think of variations or replacements, which should be covered within the protection scope of the disclosure. Therefore, the protection scope of the disclosure should be subject to the protection scope of the claims.

1. An array structure, comprising: a plurality of memory cells, a plurality of word lines and a plurality of bit lines,
wherein each of the plurality of memory cells comprises a storage structure, and a transistor arranged above the storage structure;
wherein each of the transistors comprises a columnar gate, a dielectric layer and an active layer, wherein the dielectric layer covers a sidewall and a bottom surface of the columnar gate, the active layer covers at least a sidewall of the dielectric layer, and a bottom surface of the active layer is electrically connected to the storage structure;
each of the plurality of bit lines covers sidewalls of respective active layers in a first direction; and
each of the plurality of word lines extends in a second direction and is electrically connected to top surfaces of respective columnar gates, wherein the first direction and the second direction intersect with each other and are both perpendicular to the sidewalls of the active layers.

2. The array structure according to claim 1, wherein a material of each of the active layers comprises at least one of: indium oxide, gallium oxide, zinc oxide, indium gallium oxide, indium zinc oxide, gallium zinc oxide, indium gallium zinc oxide, indium tin oxide, indium tungsten oxide, or polysilicon.

3. The array structure according to claim 1, wherein each of the storage structures comprises a lower electrode plate, a dielectric medium layer and an upper electrode plate, wherein the upper electrode plate is electrically connected to the bottom surface of a respective one of the active layers, and all of the storage structures in the array structure share the lower electrode plate.

4. The array structure according to claim 3, wherein an area of the bottom surface of each of the active layers is less than an area of a top surface of the upper electrode plate.

5. The array structure according to claim 1, wherein each of the transistors further comprises an isolation layer, wherein each of the isolation layers is arranged between a bottom surface of a respective one of the dielectric layers and the bottom surface of a respective one of the active layers.

6. The array structure according to claim 1, wherein one of a source or a drain of each of the transistors is arranged in a portion, which is in contact with the plurality of bit lines, of a respective one of the active layers, and the other one of the source or the drain of each of the transistors is arranged at a bottom portion of the respective one of the active layers.

7. A semiconductor structure, comprising: a substrate, and at least one array structure arranged above the substrate, wherein the at least one array structure comprises: a plurality of memory cells, a plurality of word lines and a plurality of bit lines,
wherein each of the plurality of memory cells comprises a storage structure, and a transistor arranged above the storage structure;
wherein each of the transistors comprises a columnar gate, a dielectric layer and an active layer, wherein the dielectric layer covers a sidewall and a bottom surface of the columnar gate, the active layer covers at least a sidewall of the dielectric layer, and a bottom surface of the active layer is electrically connected to the storage structure;
each of the plurality of bit lines covers sidewalls of respective active layers in a first direction; and
each of the plurality of word lines extends in a second direction and is electrically connected to top surfaces of respective columnar gates, wherein the first direction and the second direction intersect with each other and are both perpendicular to the sidewalls of the active layers.

8. The semiconductor structure according to claim 7, wherein the semiconductor structure comprises a plurality of array structures, wherein the plurality of array structures are stacked on one another in a direction perpendicular to the substrate.

9. The semiconductor structure according to claim 7, wherein the substrate comprises a peripheral circuit, wherein the at least one array structure is electrically connected to the peripheral circuit.

10. A method for manufacturing a semiconductor structure, comprising:
providing a substrate, and forming, on the substrate, a plurality of storage structures arranged in an array in a first direction and in a second direction, wherein the first direction and the second direction intersect with each other and are both parallel to a surface of the substrate;
forming a plurality of bit lines extending in the first direction;
forming a plurality of transistors, wherein each of the plurality of transistors is arranged above a respective one of the plurality of storage structures, and each of the plurality of transistors comprises a columnar gate, a dielectric layer and an active layer, wherein the dielectric layer covers a sidewall and a bottom surface of the columnar gate, the active layer covers at least a sidewall of the dielectric layer, and a bottom surface of the active layer is electrically connected to the respective one of the plurality of storage structures, and wherein each of the plurality of bit lines covers sidewalls of respective active layers; and
forming a plurality of word lines extending in the second direction, wherein each of the plurality of word lines is electrically connected to top surfaces of respective columnar gates.

11. The method for manufacturing the semiconductor structure according to claim 10, wherein before forming the plurality of storage structures, the method further comprises:
forming a peripheral circuit on the substrate.

12. The method for manufacturing the semiconductor structure according to claim 10, wherein forming the plurality of storage structures on the substrate comprises:
forming a first insulation layer on the substrate, and forming, in the first insulation layer, a plurality of first grooves arranged in an array in the first direction and in the second direction;
successively forming a lower electrode plate, a dielectric medium layer and an upper electrode plate material layer on a surface of the first insulation layer and inner walls of the plurality of first grooves; and
etching the upper electrode plate material layer to form a plurality of upper electrode plates arranged in an array, wherein each of the plurality of upper electrode plates corresponds to a respective one of the plurality of storage structures.

13. The method for manufacturing the semiconductor structure according to claim 12, wherein etching the upper electrode plate material layer comprises:
forming, in the upper electrode plate material layer, a plurality of first shallow trenches spaced apart from each other and extending in the first direction, and forming a plurality of second shallow trenches spaced apart from each other and extending in the second direction, wherein a bottom surface of each of the plurality of first shallow trenches and a bottom surface of each of the plurality of second shallow trenches are flush with a top surface of the dielectric medium layer, and the plurality of first shallow trenches and the plurality of second shallow trenches divide the upper electrode plate material layer into the plurality of upper electrode plates each corresponding to the respective one of the plurality of storage structures.

14. The method for manufacturing the semiconductor structure according to claim 10, wherein forming the plurality of bit lines extending in the first direction comprises:
successively forming a second insulation layer, a first conductive material layer and a third insulation layer on the plurality of storage structures, wherein the second insulation layer, the first conductive material layer and the third insulation layer are stacked on one another;
forming a plurality of third trenches which penetrate through the third insulation layer and the first conductive material layer and which extend in the first direction, wherein the plurality of third trenches divide the first conductive material layer into a plurality of first conductive wires; and
forming a plurality of vias between any two adjacent third trenches of the plurality of third trenches, wherein each of the plurality of vias penetrates through a respective one of the plurality of first conductive wires, and exposes an upper electrode plate of a respective one of the plurality of storage structures, and remaining portions of the plurality of first conductive wires form the plurality of bit lines.

15. The method for manufacturing the semiconductor structure according to claim 14, wherein forming the plurality of transistors comprises:
successively forming the active layer, an isolation layer, the dielectric layer and a second conductive material layer in each of the plurality of vias, wherein the active layer is formed on an inner wall of each of the plurality of vias, the isolation layer is formed at a bottom portion of each of the plurality of vias and covers an inner wall at a bottom portion of the active layer, the dielectric layer is formed on a surface of the sidewall of the active layer and on a top surface of the isolation layer, and the second conductive material layer is formed on a surface of the dielectric layer and is completely filled in each of the plurality of vias to form the columnar gates.

16. The method for manufacturing the semiconductor structure according to claim 10, further comprising:
doping a bottom portion of each of the active layers to form one of a source or a drain; and
doping a portion, which is in contact with the plurality of bit lines, of each of the active layers to form the other one of the source or the drain.
